(19) United States
(12) Patent Application Publication
(10) Pub. No.: US 2007/0157883 A1
(43) Pub. Date: Jul. 12, 2007

(54) Device For Coating Both Sides of Substrates With A Hydrophobic Layer

(76) Inventors: Walter Zultzke, Maintal (DE); Markus Fuhr, Eppstein (DE); Karl-Heinz Winter, Essingen (DE); Manfred Wicht, Konigsbronn (DE)

Correspondence Address: ST. ONGE STEWARD JOHNSTON & REENS, LLC, 986 BEDFORD STREET, STAMFORD, CT, 06905-5619, US

(21) Appl. No.: 11/539,427

(22) Filed: Oct. 6, 2006

Related U.S. Application Data
(63) Continuation of application No. PCT/EP05/03432, filed on Apr. 1, 2005.

(30) Foreign Application Priority Data
Apr. 6, 2004 (DE) 10 2004 018 435.6

(51) Int. Cl. C23C 16/00

(52) U.S. Cl. 118/715; 118/723 VE

(57) ABSTRACT

A device for coating both sides of a substrate with a hydrophobic layer in a vacuum coating system has a substrate holder, a first evaporator arranged one side of said substrate bolder for evaporating a substance forming the hydrophobic layer, and a second evaporator arranged on another side that is opposite from said one side.

### CROSSREFERENCE OF PENDING APPLICATION

This application is a continuation of pending international application PCT/EP 2005/003432 filed on Apr. 1, 2005 which designates US and which claims priority of German patent application No. 10 2004 018 435.6 filed on Apr. 6, 2004.

### BACKGROUND OF THE INVENTION

The invention relates to a device for coating both sides of substrates with a hydrophobic layer in a vacuum coating system, with a substrate holder and with a first evaporator, arranged on one side of the substrate holder, for evaporating a substance forming the hydrophobic layer.

A device of this type is known from DE 44 30 363 A1.

A hydrophobic, that is water-repellent, layer on a sheet-like substrate serves the purpose of preventing precipitation of moisture or attachment of moisture on the surface of the sheet-like substrate. However, this layer not only prevents attachment of moisture but also prevents attachment of any kind of dirt and also fibres or fluff. This layer also provides smoothing of the surface of the substrates.

Substrates which are provided with a hydrophobic layer are, for example, optical lenses, frame-like components or spectacle lenses of a transparent plastic or spectacle lenses of mineral glass provided with an antireflection coating.

In DE 44 30 363 A1, mentioned at the beginning, there is a description of a vacuum coating system in which sheet-like substrates can be coated with a number of layers for different purposes, and finally with a hydrophobic layer.

For instance, spectacle lenses that are produced from a substrate of transparent plastic, for example diallyl diethylene glycol carbonate, have further layers applied to them, with the intention of improving the properties of the substrate. Such layers are, for example, abrasion-resistant layers, to increase the scratch resistance, reflection-reducing layers, to achieve antireflection properties, and top layers, to cover these additionally applied layers.

Then the hydrophobic layer is applied as the outermost layer.

To apply the layers, the vacuum coating system has an evacuable chamber, in which the substrates to be treated are accommodated on a substrate holder.

The substrate holder has, for example, the form of a spherical cap, on the surface of which the individual substrates are arranged in a distributed manner. The substrates themselves are in this case held for example in spring rings.

Since a coating on both sides is desired, the spherical caps have been developed in such a way that the substrates can be turned. For this purpose, the spherical cap is subdivided into individual segments arranged one against the other in the manner of a pyramid and also referred to as paddles, which can be turned about their longitudinal axis for turning the substrates.

In such a standard vacuum system, the layers are vapor-deposited by means of an electron beam evaporator.

An optional plasma source contains a cathode emitting electrons, which are accelerated by means of a magnetic coil arrangement, to be precise from the plasma source in the direction of dome-shaped substrate holders. These accelerated electrons form a glow discharge plasma with a noble gas introduced into the vacuum system, primarily argon. The material to be coated is evaporated by the electron beam evaporator and the evaporated material passes through the plasma, being ionized and activated as it does so. Since there is no coupling between the plasma source and the evaporation source, any starting material capable of evaporation can be used in the evaporator for producing the different coatings.

The final hydrophobic layer is produced for example from tetramethyl disiloxane (TMDS).

Since the substrates have to be coated on both sides, and both the plasma source and the electron beam source are arranged on one side of the substrate holder, usually underneath the dome-shaped substrate holder, it is possible to complete the series of layers on one side of the substrate and subsequently turn the substrate and once again successively apply this series of layers.

It is also possible if turning devices are used first to apply a first layer on one side, turn the substrate and apply an identical layer on the opposite side. Subsequently, the second layer is applied on this side, the substrate is once again turned and then the second layer is applied on the opposite side.

In this way, the individual layers can then be respectively built up successively on both sides.

If the first-mentioned method is used, that is to say that the complete series of layers is applied on one side of the substrate and subsequently the substrate coated in this way on one side is turned, it has been found that, during the coating of the second side, the outermost hydrophobic layer already applied on the opposite side is unfavorably impaired.

It has been found that if, for example, an ion source is used for producing an antireflection layer, or If the so-called IAD=Ion Assisted Deposition method is used for the coating process, stray ions partially eliminate the hydrophobic effect of the layer again.

This effect can be observed all the more if the substrates are placed in spring rings, which produce a gap around the substrate.

If, in the case of devices which provide a turning capability, the layers are successively applied on both sides, numerous turning operations are necessary, in particular also a final turning operation for applying the hydrophobic layer on the two sides.

It is an object of the present invention to develop a device of the type stated at the beginning further to such an extent that sheet-like substrates can be provided with a hydrophobic layer on both sides simply and effectively.

### SUMMARY OF THE INVENTION

This object is achieved by a device for coating both sides of substrates with a hydrophobic layer in a vacuum coating system, with a substrate holder, and with a first evaporator arranged on side of the substrate holder for evaporating a substance forming a hydrophobic layer and a second evaporator is arranged on the other side that is opposite from said one said.

This measure has the advantage that, irrespective of how the substrate holder is formed, an evaporator is provided for the coating with the hydrophobic layer on both sides of the substrate.

Irrespective of which coating conditions are used during the production of the layers lying under the hydrophobic layer, and irrespective of whether these layers are applied successively on both sides or initially in each case only on one side, an evaporator is respectively available for producing the hydrophobic layer on both sides.

Applying the hydrophobic layer is less critical with respect to the dimensional stability of the layer thickness than applying for example an antireflection layer or applying a scratch-resistant layer, for which it is absolutely necessary to maintain very close layer thickness tolerances and also layer thickness structures. The hydrophobic layer, sensitive with respect to the conditions for applying these layers, in particular with respect to the ion beams, can consequently be carried out under optimum conditions specifically adapted to this layer.

There is no need for a final turning operation to be carried out to apply these hydrophobic layers, since they are applied by the two evaporators that are present on the opposite sides.

In a further configuration of the invention, the second evaporator has a container which has a number of outlet openings.

This structurally simple configuration makes it possible to carry out the additional provision of a second evaporator with extremely low cost and little expenditure on apparatus. As previously mentioned, the maintenance of close tolerance limits is not as critical here, so that it is adequate to accommodate the substance to be evaporated in the container and make it evaporate during the coating, the evaporated substance then leaving from the outlet openings.

In a further configuration of the invention, the container is releasably accommodated in a mounting.

This measure makes flexible handling possible, in particular when an existing system is being refilled or retrofitted with a second evaporator.

In a further configuration of the invention, a shutter is arranged between the container and the substrate holder.

Provision of this shutter, which likewise represents a simple component, allows the stream of substance emerging from the evaporator to be directed, shielded and/or distributed in the desired way onto the individual substrates accommodated by the substrate holder, to achieve a uniform layer thickness.

In a further configuration, the first and second evaporators are formed as individual pieces of equipment.

This measure has the advantage that, depending on the local conditions in the vacuum coating system, the two evaporators can be arranged on both sides of the substrate holder.

In a further configuration of the invention, the first and second evaporators are identically formed.

This measure contributes to further simplification and cost reduction,

In a further configuration of the invention, the first evaporator is a component of an electron beam evaporator.

This measure has the advantage that the electron beam evaporator that is present in any case in a standard vacuum system is used to serve as the first evaporator for evaporating the substances to produce the hydrophobic layer.

In a further configuration of the invention, the first evaporator is arranged below the substrate holder and the second evaporator is arranged above the substrate holder.

This measure has the advantage that, by this arrangement, the substrate holder on each of both sides can be subjected to the substance over a large surface area to build up the hydrophobic layer.

In a further configuration of the invention, the substrate holder is in the form of a spherical cap.

This measure, which is known per se, has the advantage that this customary dome-shaped substrate holder can be used, on which the layers arranged under the hydrophobic layer can then be produced in the desired quality, for example using the IAD or PIAD method, and then the hydrophobic layers can subsequently be applied on both sides by the two evaporators.

It goes without saying that the features mentioned above and those still to be explained below can be used not only in the combination specified but also in other combinations or on their own without departing from the scope of the present invention.

### BRIEF DESCRIPTION OF THE DRAWINGS

The invention is described and explained in more detail below on the basis of individual selected exemplary embodiments in connection with the accompanying drawings, in which:

FIG. 1 shows a layer structure on a substrate of plastic material,

FIG. 2 shows in a greatly schematized form a vacuum coating system for applying such layers, and

FIG. 3 shows in a greatly schematized and enlarged form an evaporator which is used for producing a hydrophobic layer in the vacuum coating system shown in FIG. 2.

### DETAILED DESCRIPTION OF PREFERRED EMBODIMENTS

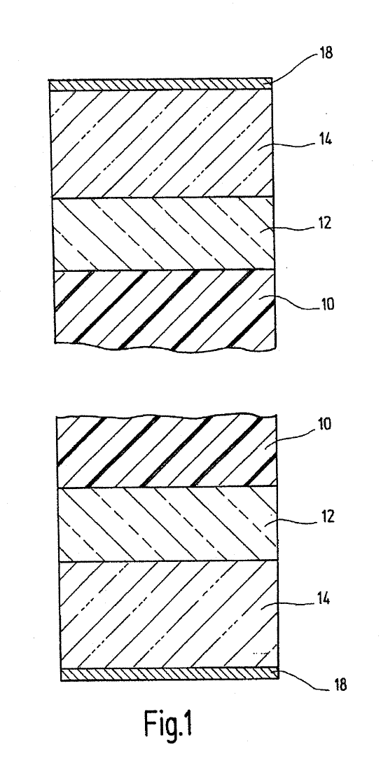

A substrate 10, represented in FIG. 1, serves as a plastic lens in a pair of spectacles.

The substrate 10 is produced for example from a thermosetting material preferred in spectacle optics with the designation CR 39, a diallyl diethylene glycol carbonate.

Further plastics for forming the substrate may be, for example, polyethylene methacrylates, polystyrenes and polycarbonates.

Firstly, an abrasion-resistant layer 12 is applied to both sides of the substrate 10, for example by a plasma ion assisted deposition method (PIAD method), as described in more detail for example in DE 44 30 363 A1.

The abrasion-resistant layer 12 consists for example of a borosilicate glass with a layer thickness of approximately 500 nanometres. The borosilicate glass has a hardness that is greater by a factor of 100 than the plastic, the hardness of which lies in the range from 180 to 200 N/min².

A reflection-reducing layer 14 is also applied to the abrasion-resistant layer 12 on both sides.

This reflection-reducing layer 14 may, for example, comprise a sequence of different oxide layers, for example TiO₂, SiO₂, TiO₂, Al₂O₃ and SiO₂.

Finally, a hydrophobic layer 18 of tetramethyl disiloxane (TMDS) is applied on both sides. The layer thickness is approximately 10-15 nm. The hydrophobic layer 18 itself comprises a three-dimensionally crosslinked SiO₂ structure with water-repellent properties.

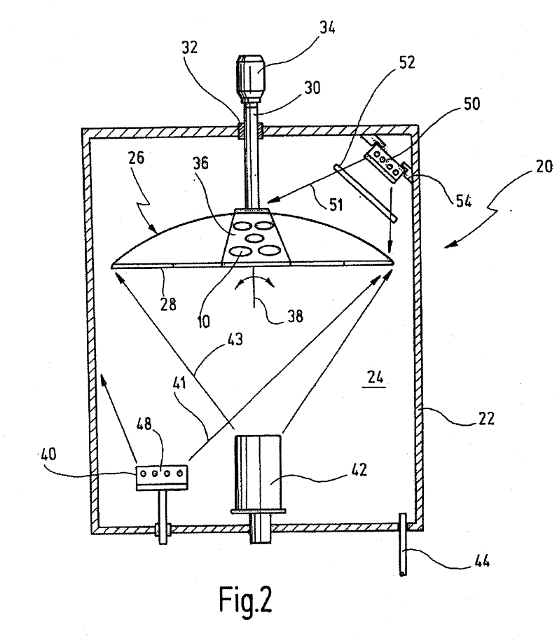

FIG. 2 shows a vacuum coating system which is provided overall with the reference numeral 20 and in which the previously mentioned different layers 12, 14 and 18 can be applied to the substrate 10.

The vacuum coating system 20 has a housing 22, inside which a chamber 24 is formed.

Accommodated in the chamber 24 is a substrate holder 26, which has the form of a spherical cap 28.

The spherical cap 28 is connected at the upper end to an axial shaft 30, which is led through a bearing 32 in the upper wall of the chamber 24 and is connected to a drive 34.

Numerous spring rings into which the substrate 10 can be pushed are provided on the substrate holder 26 in the form of a spherical cap.

The relative sizes are not shown realistically here; several dozen substrates can be accommodated on such a substrate holder.

If it is intended to work with a turning means, the spherical cap 28 may be composed of individual, approximately trapezoidal paddles 36, as indicated here, which can be turned about their longitudinal axis 38 by means of a mechanism not shown any more precisely.

Arranged under the spherical cap 28 is an electron beam evaporator 40, in which the materials that are intended to form the individual layers can be evaporated.

The material evaporated by the electron beam evaporator 40 is expelled in a jet, as indicated by the arrows 41, in the direction of the substrate holder 26.

The starting materials that can undergo evaporation, for example oxides and fluorides, may be used as granules or as sheets.

The evaporating of the material is accomplished by applying a corresponding negative pressure in the chamber 24 (for example 10⁻⁶ mbar) and heating the material in the electron beam evaporator 40.

Precise conditions are described for example in DE 44 30 363 A1, to which reference is expressly made here.

Also arranged under the substrate holder 46 is a plasma source 42, which produces a plasma stream, as represented in FIG. 2 by the arrows 43.

The plasma source 42 has, for example, a cylindrical electron-emitting LaB₆ cathode, which is surrounded by a cylindrical anode. In this case, a glow discharge plasma is produced, a noble gas, primarily argon, being introduced into the chamber 24 via a line 44. A cylindrical magnetic coil which surrounds the anode brings about the effect that the mobility of the electrons which produce the plasma is considerably increased in the axial direction and considerably reduced in the radial direction. Arranged in the region of the upper wall of the coating chamber and above the substrate holder is an annular magnetic coil—not represented any more precisely here. The magnetic field of this annular coil is superposed with the magnetic field of the cylindrical coil surrounding the anode and leads to the plasma, a dome-shaped plasma boundary layer being produced upstream of the dome-shaped substrate holder. On account of the negative potential of the substrate holder 26 in relation to the plasma, ions are accelerated out of the plasma boundary layer and bombard a growing film, which as a result is compacted. The material evaporated by the electron beam evaporator 40 is likewise ionized and activated.

The independent form of the electron beam evaporator 40 and the plasma source 42 allows the electron beam evaporator 40 to be charged with the respectively suitable material, for example also with the material for producing the final hydrophobic layer 18, that is to say for example tetramethyl disiloxane (TMDS).

This means that the electron beam evaporator 40 operates in this case as a first evaporator 48 for evaporating the material for forming the hydrophobic layer 18 on the side of the substrate 10 that is facing the bottom of the chamber 24.

As FIG. 2 reveals, a second evaporator 50 is arranged on the opposite side of the substrates 10, that is to say above the substrate holder 26.

The second evaporator 50 is arranged laterally above the substrate holder 26 and is held in the chamber 24 by means of a mounting 54.

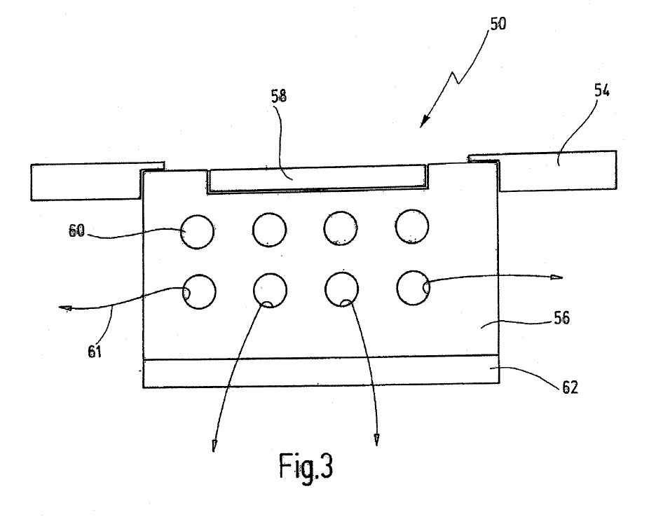

This second evaporator 50 is shown in more detail in FIG. 3.

The second evaporator 50 has a container 56 which is closed on all sides in the form of a boat, which has a displaceable cover 58.

In the side walls, in particular in the side wall which is facing the substrate holder 26, numerous openings 60 are provided, serving to allow the material that is accommodated in the evaporator 50 to leave after it has been evaporated, as is represented by the arrows 61.

At the bottom, the container 56 is provided with a heater 62.

Returning to FIG. 2, this reveals that also arranged between the second evaporator 50 and the upper side of the substrate holder 26 is a shutter 52, which serves for the focusing or blocking out of the evaporated material leaving the second evaporator 50, in order in this way to accomplish a correspondingly desired distribution of this material onto the upper side of the substrate holder 26.

The substrate holder 26, which rotates about the axial shaft 30, is correspondingly made to pass gradually through under the shutter 52.

In the previously described exemplary embodiment, the lower first evaporator 48 is part of the electron beam evaporator 40, which is used to evaporator all the materials to be applied in layers.

In the further exemplary embodiment, not presented here, it is provided that two second evaporators 50 are arranged mirror-symmetrically, that is to say one above the substrate holder 26 and one under the substrate holder 26.

These two evaporators then operate entirely independently of the electron beam evaporator, which is then merely used for building up the layers lying under the hydrophobic layer.

This shows the flexibility and also the possibility of merely retrofitting already existing systems with a second evaporator 50.

What is claimed is:

1. A device for coating both sides of a substrate with a hydrophobic layer in a vacuum coating system, comprising
a substrate holder,
a first evaporator, arranged on one side of said substrate holder for evaporating a substance forming the hydrophobic layer, and
a second evaporator arranged on an other side that is opposite from said one side.

2. The device of claim 1, wherein said second evaporator has a container which has a number of outlet openings.

3. The device of claim 1, wherein said container is releasably accommodated in a mounting.

4. The device of claim 1, wherein a shutter is arranged between said second evaporator and said substrate holder.

5. The device of claim 1, wherein said first and said second evaporators are formed as individual pieces of equipment.

6. The device of claim 1, wherein said first and said second evaporators are identically formed.

7. The device of claim 1, wherein said first evaporator is a component of an electron beam evaporator.

8. The device of claim 1, wherein said first evaporator is arranged below said substrate holder and said second evaporator is arranged above said substrate holder.

9. The device of claim 1, wherein said substrate holder has the shape of a spherical cap.
